(19) United States
(12) Patent Application Publication
(10) Pub. No.: US 2026/0022449 A1
(43) Pub. Date: Jan. 22, 2026

(54) METHOD FOR MANUFACTURING PATTERNED SURFACE COATING AND AUTOMOBILE HEAT DISSIPATION DEVICE HAVING PATTERNED SURFACE COATING

(71) Applicant: AMULAIRE THERMAL TECHNOLOGY, INC., New Taipei City (TW)

(72) Inventors: YI-HSIN HUANG, New Taipei City (TW); CHING-MING YANG, New Taipei City (TW); TZE-YANG YEH, New Taipei City (TW)

(21) Appl. No.: 19/340,575

(22) Filed: Sep. 25, 2025

Related U.S. Application Data
(63) Continuation-in-part of application No. 17/577,228, filed on Jan. 17, 2022.

(51) Int. Cl. C23C 14/04; H05K 7/20

(52) U.S. Cl. CPC C23C 14/042; H05K 7/20854

(57) ABSTRACT

A method for manufacturing a patterned surface coating of an automobile heat dissipation device and an automobile heat dissipation device having a patterned surface coating. The method for manufacturing the patterned surface coating of the automobile heat dissipation device includes providing a metal heat dissipation device, and forming a sputtered metal layer that is patterned on an upper surface of the metal heat dissipation device by sputtering, allowing a thickness of the sputtered metal layer to be between 1 μm and 3 μm, and allowing the sputtered metal layer to cover an area less than 90% of an area of the upper surface of the metal heat dissipation device.

### CROSS-REFERENCE TO RELATED PATENT APPLICATION

This Application is a Continuation-in-Part of the U.S. patent application Ser. No. 17/577,228, filed on Jan. 17, 2022, and entitled “METHOD FOR MANUFACTURING PATTERNED SURFACE COATING AND AUTOMOBILE HEAT DISSIPATION DEVICE HAVING PATTERNED SURFACE COATING,” now pending, the entire disclosures of which are incorporated herein by reference.

### FIELD OF THE DISCLOSURE

The present disclosure relates to an automobile heat dissipation device, and more particularly to a method for manufacturing a patterned surface coating of an automobile heat dissipation device and an automobile heat dissipation device having a patterned surface coating.

### BACKGROUND OF THE DISCLOSURE

Overheating of conventional automobile electronic modules, such as insulated gate bipolar transistor (IGBT) modules and advanced driver-assistance system (ADAS) modules, may result in deterioration of performance and damage thereof.

Metal heat dissipation devices are usually used for the conventional automobile electronic modules. However, with the rapid development of modern industry, there are higher demands on the functionality of the metal heat dissipation devices, such as a corrosion resistant ability or a bonding strength thereof, which cannot be met by conventional metal heat dissipation devices.

### SUMMARY OF THE DISCLOSURE

In response to the above-referenced technical inadequacies, the present disclosure provides a method for manufacturing a patterned surface coating of an automobile heat dissipation device and an automobile heat dissipation device having a patterned surface coating.

In one aspect, the present disclosure provides a method for manufacturing a patterned surface coating of an automobile heat dissipation device, and the method includes (a) providing a metal heat dissipation device; and (b) forming a sputtered metal layer that is patterned on an upper surface of the metal heat dissipation device by sputtering, allowing a thickness of the sputtered metal layer to be between 1 μm and 3 μm, and allowing the sputtered metal layer to cover an area less than 90% of an area of the upper surface of the metal heat dissipation device. At least one selectively removable masking area is formed on the upper surface of the metal heat dissipation device, so that the sputtered metal layer is not formed in the at least one selectively removable masking area.

In certain embodiments, the at least one selectively removable masking area is formed by at least one electroplating tape that is selectively removable and has a self-adhesive coating.

In certain embodiments, at least one cooling fin is joined to the bottom surface of the metal heat dissipation device, and at least one internal coolant passage is defined between the metal heat dissipation device and the at least one cooling fin.

In certain embodiments, the at least one cooling fin is a single continuous fin.

In certain embodiments, the at least one cooling fin is disposed between the metal heat dissipation device and an outer cover.

In certain embodiments, the outer cover is a closed outer cover.

In certain embodiments, the outer cover is a semi-open outer cover.

In certain embodiments, the at least one cooling fin is joined to the bottom surface of the metal heat dissipation device by brazing, adhesive bonding, or solid-state welding.

In another aspect, the present disclosure provides an automobile heat dissipation device having a patterned surface coating, which includes a metal heat dissipation device and a sputtered metal layer. The sputtered metal layer is partially formed on an upper surface of the metal heat dissipation device by sputtering so that the sputtered metal layer is patterned. A thickness of the sputtered metal layer is between 1 μm and 3 μm, and the sputtered metal layer covers an area less than 90% of an area of the upper surface of the metal heat dissipation device. At least one selectively removable masking area is formed on the upper surface of the metal heat dissipation device, so that the sputtered metal layer is not formed in the at least one selectively removable masking area.

Therefore, in the method for manufacturing the patterned surface coating of the automobile heat dissipation device and the automobile heat dissipation device having the patterned surface coating provided by the present disclosure, by virtue of “providing the metal heat dissipation device” and “forming the sputtered metal layer that is patterned on the upper surface of the metal heat dissipation device by sputtering, allowing the thickness of the metal sputtered layer to be between 1 μm and 3 μm, and allowing the sputtered metal layer to cover the area less than 90% of the area of the upper surface of the metal heat dissipation device,” a functional area that is patterned is formed on the upper surface of the metal heat dissipation device, so as to effectively enhance a soldering functionality, a corrosion resistant property, or a sintering ability of the metal heat dissipation device.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a metal heat dissipation device according to one embodiment of the present disclosure;

FIG. 2 is a schematic side view of the metal heat dissipation device having a sputtered metal layer that is pattered and formed on an upper surface thereof according to one embodiment of the present disclosure; and

FIG. 3 is a schematic side view of another metal heat dissipation device and a cooling structure according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### Embodiments

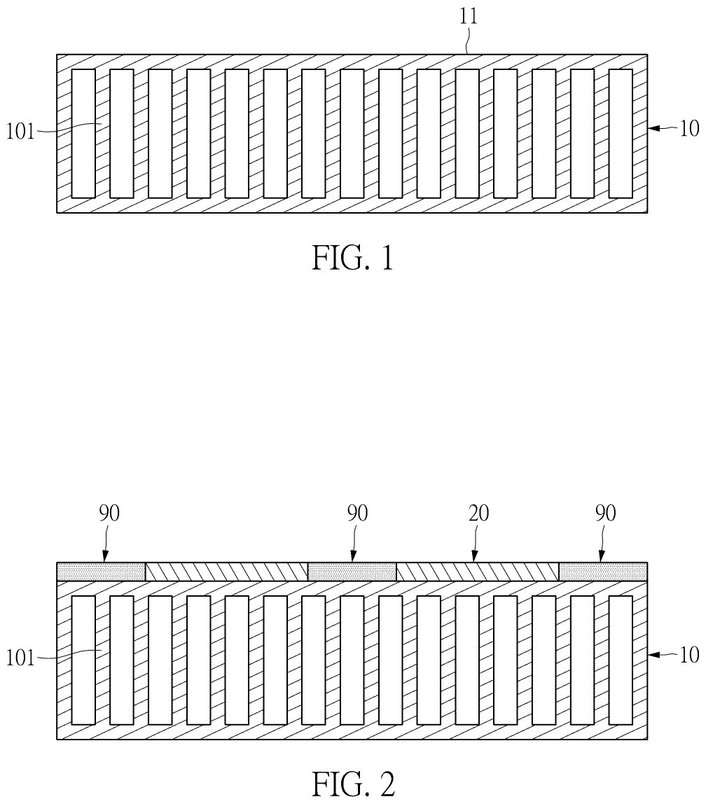

Referring to FIG. 1 and FIG. 2, embodiments of the present disclosure provide a method for manufacturing a patterned surface coating of an automobile heat dissipation device, and the method includes the following steps.

In step (a), a metal heat dissipation device 10 is provided. Further, in the present embodiment, a fin structure 101 is disposed in the metal heat dissipation device 10, and the fin structure 101 can be a plate fin or a pin fin, but is not limited thereto. Furthermore, the metal heat dissipation device 10 can be a water-cooled metal heat dissipation device or an air-cooled metal heat dissipation device, or be a closed metal heat dissipation device or a semi-open metal heat dissipation device. Further, the metal heat dissipation device 10 can be made of at least one of aluminum, aluminum alloy, copper, and copper alloy.

In step (b), a sputtered metal layer 20 that is patterned is formed on an upper surface 11 of the metal heat dissipation device 10 by sputtering. Further, at least one selectively removable masking area 90 is formed on the upper surface 11 of the metal heat dissipation device 10 by a masking process, such as by arranging a masking jig on the surface of the metal heat dissipation device 10, by printing ink on the surface of the metal heat dissipation device 10, and by arranging an electroplating tape on the surface of the metal heat dissipation device 10, so that a metal layer is not formed in the at least one selectively removable masking area 90, thereby forming the sputtered metal layer 20 that is patterned on the upper surface 11 of the metal heat dissipation device 10.

In one embodiment, the sputtered metal layer 20 can be formed by sputtering a single metal. The single metal can be nickel, copper, or silver. Therefore, the sputtered metal layer 20 can be a sputtered nickel layer, a sputtered copper layer, or a sputtered silver layer.

In one embodiment, the sputtered metal layer 20 can be formed by sputtering an alloy metal. The alloy metal can be nickel alloy, copper alloy, or silver alloy. Therefore, the sputtered metal layer 20 can also be a sputtered nickel alloy layer, a sputtered copper alloy layer, or a sputtered silver alloy layer.

It is worth mentioning that, a thickness of the metal sputtered layer 20 is preferably between 1 μm and 3 μm, and the sputtered metal layer 20 covers an area less than 90% of an area of the upper surface 11 of the metal heat dissipation device 10.

Furthermore, the sputtered metal layer 20 is formed at a vacuum level of less than 10⁻² mbar. In addition, the sputtered metal layer 20 is formed at a sputtering power of 1000 W or more, so that a film formed by sputtering has high purity, good compactness, and uniformity of molding.

Therefore, through forming the sputtered metal layer 20 that is patterned on the upper surface 11 of the metal heat dissipation device 10, a functional area that is patterned is formed on the upper surface 11 of the metal heat dissipation device 10, so as to effectively enhance a soldering ability, a corrosion resistant property, or a sintering ability of the metal heat dissipation device 10.

Furthermore, according to the above, the embodiments of the present disclosure also provide an automobile heat dissipation device having a patterned surface coating, and the automobile heat dissipation device includes a metal heat dissipation device 10 and a sputtered metal layer 20. Further, the sputtered metal layer 20 is partially formed on an upper surface 11 of the metal heat dissipation device 10 by sputtering, so that the sputtered metal layer 20 is patterned and a thickness of the sputtered metal layer 20 is between 1 μm and 3 μm. In addition, the sputtered metal layer covers an area less than 90% of an area of the upper surface 11 of the metal heat dissipation device 10.

In one embodiment, the metal heat dissipation device 10 can have a fin structure 101 disposed therein. The metal heat dissipation device 10 can be a water-cooled metal heat dissipation device or an air-cooled metal heat dissipation device. The metal heat dissipation device 10 can be a closed metal heat dissipation device or a semi-open metal heat dissipation device. In addition, the metal heat dissipation device 10 can be made of at least one of aluminum, aluminum alloy, copper, and copper alloy.

In one embodiment, the sputtered metal layer 20 can be made of nickel, nickel alloy, copper, copper alloy, silver, or silver alloy.

In one embodiment, the at least one selectively removable masking area 90 is formed on the upper surface 11 of the metal heat dissipation device 10, so that the sputtered metal layer 20 is not formed in the at least one selectively removable masking area 90.

In one embodiment, the at least one selectively removable masking area 90 is formed by at least one electroplating tape that is selectively removable and has a self-adhesive coating 901.

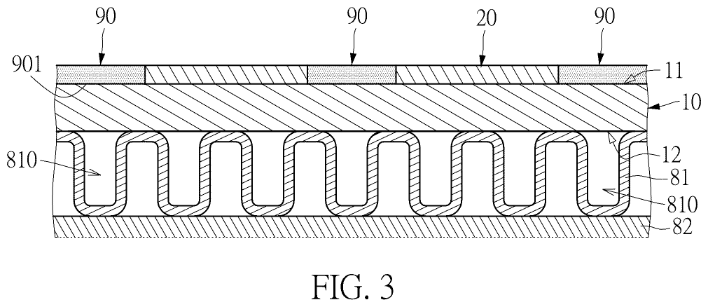

In one embodiment, a cooling structure is joined to the bottom surface 12 of the metal heat dissipation device 10 as shown in FIG. 3. The cooling structure can be one or more cooling fins 81 arranged in parallel. The cooling fin 81 is a single continuous fin that has a series of upper and lower U-bends. However, in other embodiments, other shapes or configurations for the cooling fin may be applicable. The cooling fin 81 can be made of one of copper, copper alloy, aluminum, and aluminum alloy. The cooling fin 81 can also be made of a metal alloy having excellent heat transfer characteristics. The discontinuous top portion of the cooling fin 81 is generally flat, which provides a large area for brazing and assisting in the flow of heat out from the metal heat dissipation device into the cooling fin 81. Preferably, the cooling fin 81 is brazed to the bottom surface 12 of the metal heat dissipation device 10. The cooling fin 81 can also be joined to the bottom surface 12 of the metal heat dissipation device 10 by adhesive bonding or solid-state welding. Further, at least one internal coolant passage 810 is defined between the metal heat dissipation device 10 and the at least one cooling fin 81, so as to enhance heat dissipation efficiency of the metal heat dissipation device 10.

Moreover, the cooling fin 81 is disposed between the metal heat dissipation device 10 and an outer cover 82. The outer cover 82 can be joined to the cooling fin 81. The outer cover 82 can be a closed outer cover or a semi-open outer cover having one or more holes or openings that allow the coolant (e.g., water or ethylene glycol) to enter and exit the at least one internal coolant passage 810, thereby rapidly carrying away high heat. In addition, the outer cover 82 can be made of at least one of aluminum, aluminum alloy, copper, and copper alloy.

### Beneficial Effects of the Embodiments

In conclusion, in the method for manufacturing the patterned surface coating of the automobile heat dissipation device and the automobile heat dissipation device having the patterned surface coating provided by the present disclosure, by virtue of “providing the metal heat dissipation device” and “forming the sputtered metal layer that is patterned on the upper surface of the metal heat dissipation device by sputtering, allowing the thickness of the metal sputtered layer to be between 1 μm and 3 μm, and allowing the sputtered metal layer to cover the area less than 90% of the area of the upper surface of the metal heat dissipation device,” the functional area that is patterned is formed on the upper surface of the metal heat dissipation device, so as to effectively enhance the soldering ability, the corrosion resistant property, or the sintering ability of the metal heat dissipation device.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing a patterned surface coating of an automobile heat dissipation device, comprising:
(a) providing a metal heat dissipation device; and
(b) forming a sputtered metal layer that is patterned on an upper surface of the metal heat dissipation device by sputtering, allowing a thickness of the sputtered metal layer to be between 1 μm and 3 μm, and allowing the sputtered metal layer to cover an area less than 90% of an area of the upper surface of the metal heat dissipation device;
wherein at least one selectively removable masking area is formed on the upper surface of the metal heat dissipation device, so that the sputtered metal layer is not formed in the at least one selectively removable masking area.

2. The method according to claim 1, wherein the at least one selectively removable masking area is formed by at least one electroplating tape that is selectively removable and has a self-adhesive coating.

3. The method according to claim 1, wherein at least one cooling fin is joined to a bottom surface of the metal heat dissipation device, and at least one internal coolant passage is defined between the metal heat dissipation device and the at least one cooling fin.

4. The method according to claim 3, wherein the at least one cooling fin is a single continuous fin.

5. The method according to claim 4, wherein the at least one cooling fin is disposed between the metal heat dissipation device and an outer cover.

6. The method according to claim 5, wherein the outer cover is a closed outer cover.

7. The method according to claim 5, wherein the outer cover is a semi-open outer cover.

8. The method according to claim 1, wherein the at least one cooling fin is joined to the bottom surface by brazing, adhesive bonding, or solid-state welding.

9. An automobile heat dissipation device having a patterned surface coating, comprising:
a metal heat dissipation device; and
a sputtered metal layer partially formed on an upper surface of the metal heat dissipation device by sputtering so that the sputtered metal layer is patterned, wherein a thickness of the sputtered metal layer is between 1 μm and 3 μm, and the sputtered metal layer covers an area less than 90% of an area of the upper surface of the metal heat dissipation device;
wherein at least one selectively removable masking area is formed on the upper surface of the metal heat dissipation device, so that the sputtered metal layer is not formed in the at least one selectively removable masking area.

10. The automobile heat dissipation device according to claim 9, wherein the at least one selectively removable masking area is formed by at least one electroplating tape that is selectively removable and has a self-adhesive coating.

11. The automobile heat dissipation device according to claim 9, wherein at least one cooling fin is joined to a bottom surface of the metal heat dissipation device, and at least one internal coolant passage is defined between the metal heat dissipation device and the at least one cooling fin.

12. The automobile heat dissipation device according to claim 11, wherein the at least one cooling fin is a single continuous fin.

13. The automobile heat dissipation device according to claim 12, wherein the at least one cooling fin is disposed between the metal heat dissipation device and an outer cover.

14. The automobile heat dissipation device according to claim 13, wherein the outer cover is a closed outer cover.

15. The automobile heat dissipation device according to claim 13, wherein the outer cover is a semi-open outer cover.

16. The automobile heat dissipation device according to claim 9, wherein the at least one cooling fin is joined to the bottom surface by brazing, adhesive bonding, or solid-state welding.
